(19) United States
(12) Patent Application Publication
(10) Pub. No.: US 2025/0208519 A1
(43) Pub. Date: Jun. 26, 2025

(54) EXPOSURE EQUIPMENT

(71) Applicant: SAMSUNG ELECTRONICS CO., LTD., SUWON-SI (KR)

(72) Inventors: Jisu KIM, Suwon-si (KR); Myungsik LEE, Suwon-si (KR); Weonchan SUNG, Suwon-si (KR); Yunha KIM, Suwon-si (KR); Janghwan KIM, Suwon-si (KR)

(21) Appl. No.: 18/783,670

(22) Filed: Jul. 25, 2024

(30) Foreign Application Priority Data
Dec. 20, 2023 (KR) 10-2023-0187523

(51) Int. Cl. G03F 7/00

(52) U.S. Cl. CPC G03F 7/70558; G03F 7/70033; G03F 7/70725

(57) ABSTRACT

Provided is a wafer exposure time inspection device including an estimation circuit configured to estimate a minimum step time or an optimal exposure speed. In the minimum step time, a step time during which an exposure device completes exposure for one shot area from among a plurality of shot areas on a wafer and moves to a next shot area is minimized, and in the optimal exposure speed, a sum of the step time and a scan time during which the shot area is exposed is minimized. A comparison circuit configured to compare a measured wafer exposure time with a first optimal wafer exposure time calculated from the minimum step time and the scan time or compare the measured wafer exposure time with a second optimal wafer exposure time calculated from the estimated optimal exposure speed.

### CROSS-REFERENCE TO RELATED APPLICATION

This application is based on and claims priority under 35 U.S.C. § 119 to Korean Patent Application No. 10-2023-0187523, filed on Dec. 20, 2023, in the Korean Intellectual Property Office, the disclosure of which is incorporated by reference herein in its entirety.

### 1. TECHNICAL FIELD

The present disclosure relates to wafer exposure and, more specifically, to a wafer exposure time inspection device and exposure equipment including the wafer exposure time inspection device

### 2. DISCUSSION OF THE RELATED ART

During a semiconductor manufacturing process, an exposure process exposes a wafer to light so that fine circuit patterns are sequentially engraved in shot areas that are present in a rectangular array within the wafer. The exposure process is performed by an exposure device. The exposure device projects the pattern from a reticle onto the wafer's surface, simultaneously maneuvering both a reticle stage, which patterned reticle is formed, and a wafer stage, which positions the wafer.

A time it takes to expose all shot areas within the wafer is referred to as a wafer exposure time. The wafer exposure time is determined by various factors such as the total number of shot areas within the wafer, a size of each of the shot areas, an exposure speed, an exposure sequence, operation capabilities, a movement path, a settling time, or the like of the wafer stage and the reticle stage.

The exposure process accounts for 35% or more of a semiconductor production cost and 60% or more of a process time. Inspecting and minimizing the wafer exposure time of the exposure time may increase productivity not only in the exposure process but also in the entire semiconductor process.

### SUMMARY

The inventive concept provides a wafer exposure time inspection device capable of inspecting appropriateness of a wafer exposure time, and exposure equipment including the wafer exposure time inspection device.

The objective of the technical idea of the inventive concept is not necessarily limited to the objective described above, and other objectives could be clearly understood by those skilled in the art from the following description.

According to an aspect of the inventive concept, there is provided a wafer exposure time inspection device including an estimation circuit configured to estimate a minimum step time or an optimal exposure speed, wherein, in the minimum step time, a step time during which an exposure device completes exposure for one shot area from among a plurality of shot areas on a wafer and moves to a next shot area is minimized, and in the optimal exposure speed, a sum of the step time and a scan time during which the shot area is exposed is minimized and a comparison circuit configured to compare a measured wafer exposure time with a first optimal wafer exposure time calculated from the minimum step time and the scan time or compare the measured wafer exposure time with a second optimal wafer exposure time calculated from the estimated optimal exposure speed. The first and second optimal wafer exposure time are times during which a wafer exposure time is minimized, the wafer exposure time being a sum of a scan time for exposure for each of all shot areas of the wafer with a step time for movement between the shot areas.

According to an aspect of the inventive concept, there is provided exposure equipment including an exposure device configured to transfer a pattern of a reticle to a wafer using light and a wafer exposure time inspection device configured to inspect appropriateness of a wafer exposure time during which the wafer is illuminated to transfer the pattern to the wafer. The wafer exposure time inspection device includes an estimation circuit configured to estimate a minimum step time or an optimal exposure speed, wherein, in the minimum step time, a step time during which exposure for one shot area from among a plurality of shot areas on the wafer is completed and the wafer exposure device moves to a next shot area is minimized, and in the optimal exposure speed, a sum of the step time and a scan time during which the shot area is exposed is minimized, a comparison circuit configured to compare a measured wafer exposure time with a first optimal wafer exposure time calculated from the minimum step time and the scan time or compare a measured wafer exposure time with a second optimal wafer exposure time calculated from the estimated optimal exposure speed and a check circuit configured to identify whether an exposure speed is set in the exposure device. In the optimal wafer exposure time, a sum of a wafer exposure time, which is a sum of a scan time during which each of all shot areas of the wafer is exposed, with a step time during which the exposure device moves between the shot areas is minimized.

According to an aspect of the inventive concept, there is provided an exposure device configured to transfer a pattern of a reticle to a wafer by using light and a wafer exposure time inspection device configured to inspect appropriateness of a wafer exposure time during which the wafer is illuminated to transfer the pattern to the wafer. The wafer exposure time inspection device includes an estimation circuit configured to estimate a minimum step time or an optimal exposure speed, wherein, in the minimum step time, a step time during which exposure for one shot area from among a plurality of shot areas on the wafer is completed and the exposure device moves to a next shot area is minimized, and in the optimal exposure speed, a sum of the step time and a scan time during which the shot area is exposed is minimized, a comparison circuit configured to compare a measured wafer exposure time with a first optimal wafer exposure time calculated from the minimum step time and the scan time or compare a measured wafer exposure time with a second optimal wafer exposure time calculated from the estimated optimal exposure speed and a check circuit configured to identify whether an exposure speed is set in the exposure device. In the optimal wafer exposure time, a sum of a wafer exposure time, which is a sum of a scan time during which each of all shot areas of the wafer is exposed, with a step time during which the exposure device moves between the shot areas is minimized, and the exposure device including a reticle stage on which a reticle having a pattern formed therein is arranged, an illumination source configured to generate ultraviolet (UV) light and emit the generated UV light toward the reticle, a first optical system configured to allow the UV light from the UV source to be incident on the reticle, a second optical system in which the reticle transmits the UV light that is reflected, refracted, or transmitted and a wafer stage on which a wafer through which the UV light passing through the second optical system is projected and to which the pattern is transferred is arranged. The estimation circuit is further configured to estimate the minimum step time or the optimal exposure speed by modeling, by using at least a 3rd-order system, a time model for each of displacement of a wafer stage of the exposure device in a first direction, displacement of the wafer stage in a second direction, and displacement of a reticle stage in a third direction. The first direction is perpendicular to the second direction in which the shot area is exposed, and the third direction is parallel to the second direction.

### BRIEF DESCRIPTION OF THE DRAWINGS

Embodiments of the inventive concept will be more clearly understood from the following detailed description taken in conjunction with the accompanying drawings in which:

FIG. 1 is a configuration diagram schematically illustrating exposure equipment according to an embodiment;

FIG. 2 is a configuration diagram schematically illustrating an exposure device of FIG. 1 according to an embodiment;

FIG. 3 is a configuration diagram schematically illustrating the exposure device of FIG. 1 according to another embodiment;

FIG. 4 is a configuration diagram schematically illustrating a wafer exposure time inspection device of FIG. 1;

FIG. 5 is a diagram illustrating a movement trajectory of a wafer stage;

FIG. 6 is a graph showing a one-shot exposure time according to changes in scan speed; and

FIG. 7 is a flowchart of a method of inspecting a wafer exposure time, according to an embodiment.

### DETAILED DESCRIPTION OF THE EMBODIMENTS

Hereinbelow, embodiments are described in detail with reference to the accompanying drawings. To the extent that an element has not been described in detail, it may be assumed that the element is at least similar to corresponding elements that have been described in previous figures.

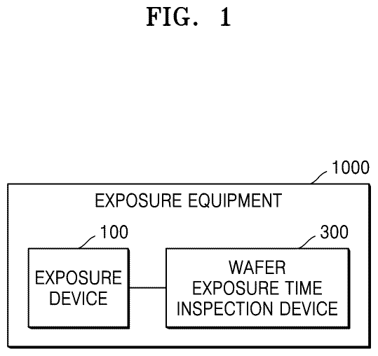

FIG. 1 is a configuration diagram schematically illustrating exposure equipment 1000 according to an embodiment. Referring to FIG. 1, the exposure equipment 1000, according to an embodiment, may include an exposure device 100 and a wafer exposure time inspection device 300.

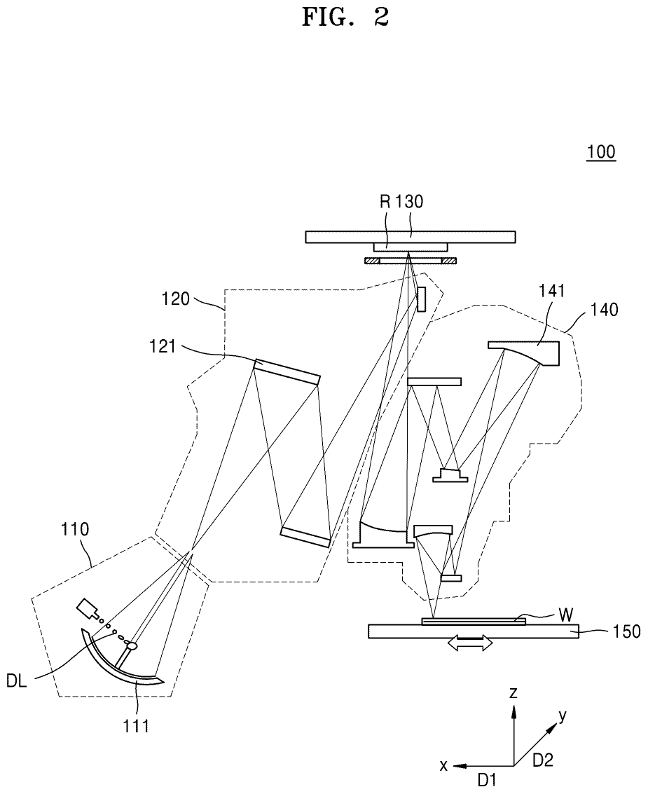

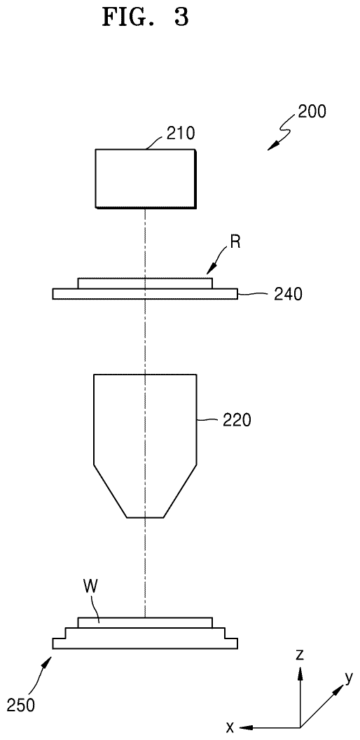

The exposure device 100 may transfer a pattern on a reticle onto a wafer by using light generated from a light source. The exposure device 100 may include a light source, a reticle stage, a wafer stage, and an optical system. The exposure device 100 may be of a reflective type in which light generated from the light source is reflected by the reticle and transferred to the wafer or a transmissive type in which the light passes through the reticle and is transmitted to the wafer. The exposure device 100 is described with reference to FIGS. 2 and 3.

The wafer exposure time inspection device 300 may estimate an optimal wafer exposure time of the exposure device 100, and inspect whether the exposure process of the exposure device 100 is efficiently performed by comparing the estimated optimal wafer exposure time with a measured wafer exposure time. For example, the wafer exposure time may be the sum of a scan time for exposing each shot area of the wafer and a step time for moving between the shot areas. The wafer exposure time may be determined by the number of shot areas of the wafer, a size of the shot area, an exposure speed, an exposure sequence, and operation capabilities, movement path, settling time, or the like of the wafer stage and the reticle stage. The wafer exposure time inspection device 300 may estimate a theoretical wafer exposure time that may be achieved by the exposure device 100, and compare the estimated wafer exposure time with a measured wafer exposure time. As a result of the comparison above, when a difference between the estimated wafer exposure time and the measured wafer exposure time is within a certain range, the wafer exposure time inspection device 300 may determine that the exposure process of the exposure device 100 is appropriate, but when the difference between the estimated wafer exposure time and the measured wafer exposure time exceeds the certain range, the wafer exposure time inspection device 300 may determine that the exposure process of the exposure device 100 is not appropriate.

When it is determined that the exposure process of the exposure device 100 is not appropriate, the wafer exposure time inspection device 300 may provide a minimum step time or an optimal exposure speed, thus increasing the productivity of the exposure device.

FIG. 2 is a configuration diagram schematically illustrating the exposure device 100 of FIG. 1 according to an embodiment.

Referring to FIG. 2, the exposure device 100 of the present embodiment may be an extreme ultra violet (EUV) exposure device. The ultraviolet (UV) exposure device 100 may include a UV source 110, a first optical system 120, a reticle stage 130, a second optical system 140, and a wafer stage 150.

The UV source 110 may generate and output EUV light with high energy density within a wavelength range of about 5 nm to about 50 nm. For example, the UV source 110 may generate and output the EUV light with high energy density with a wavelength of about 13.5 nm.

The UV source 110 may be a plasma-based source or a synchrotron radiation source. Herein, the plasma-based source may refer to a source that generates plasma and uses light emitted by the plasma, and may include a laser-produced plasma (LPP) source, a discharge-produced plasma (DPP), or the like. For example, in the LPP source, EUV light may be generated from tin plasma generated by condensing high-power carbon dioxide (CO₂) laser on a tin droplet (DP).

In the UV exposure device 100 of the present embodiment, the UV source 110 may be, for example, a plasma-based source. However, in the UV source 110 of the present embodiment, the UV source 110 is not necessarily limited to the plasma-based source. Meanwhile, in order to increase energy density of illumination light incident on the first optical system 120, the plasma-based source may include a condensing mirror 111 such as an elliptical mirror and/or a spherical mirror to focus EUV light. The condensing mirror 111 may be referred to as a EUV collector.

The first optical system 120 may include a plurality of mirrors 121. For example, in the UV exposure device 100 of the present embodiment, the first optical system 120 may include two or three mirrors 121. However, the number of mirrors in the first optical system 120 is not necessarily limited to two or three and may vary.

The first optical system 120 may transfer the EUV light from the UV source 110 to a reticle R. Herein, the reticle R may refer to a EUV mask. For example, the EUV light emitted by the UV source 110 may be incidentally directed onto the reticle stage 130 by reflection off the mirrors 121 disposed in the first optical system 120.

Meanwhile, the first optical system 120 may make the EUV light a curved slit shape and may allow the EUV light to be directed onto the reticle R. Herein, the curved slit shape of EUV light may refer to a parabolic two-dimensional curve on an x-y plane.

The reticle R may be a reflective mask including a reflective area and a non-reflective and/or intermediate reflective area. The reticle R may include a reflective multi-layer film for reflecting EUV onto a substrate that is formed of a low thermal expansion coefficient material (LTEM) such as quartz, and an absorption layer pattern formed on the reflective multi-layer film.

For example, the reflective multi-layer film may have a structure in which a molybdenum (Mo) layer and a silicon (Si) layer are alternately stacked in dozens or more layers. The absorption layer may include, for example, tantalum nitride (TaN), tantalum nitrogen oxide (TaNO), tantalum boron oxide (BaBO), nickel (Ni), gold (Au), silver (Ag), carbon (C), tellurium (Te), platinum (Pt), palladium (Pd), chromium (Cr), or the like. However, the material of the reflective multi-layer film and the material of the absorption layer are not necessarily limited to the materials described above. Here, the absorption layer portion may correspond to the non-reflective and/or intermediate reflective area described above. Meanwhile, a capping layer formed of zirconium dioxide (ZrO₂) may be disposed on an upper surface of the reflective multi-layer film, and the absorption layer may be disposed on the capping layer.

The reticle R may reflect the EUV light incident from the first optical system 120, directing the reflected EUV light to onto the second optical system 140. For example, the reticle R may reflect EUV light from the first optical system 120 and structure the EUV light according to a pattern composed of an absorption layer on the reflective multi-layer film to allow the structured EUV light to be incident on the second optical system 140. The structured EUV light may be incident on the second optical system 140 while retaining information in the form of a pattern on the reticle R. In addition, the structured EUV light may be transmitted through the second optical system 140 and projected onto a EUV exposure target. Accordingly, an image corresponding to the pattern on the reticle R may be transferred to the EUV exposure target.

Herein, the EUV exposure target may be a substrate containing a semiconductor material such as silicon, for example, a wafer W. Hereinbelow, unless otherwise specified, the EUV exposure target and the wafer W are used as the same concept.

The second optical system 140 may include a plurality of mirrors 141. In the UV exposure device 100 of the present embodiment, the second optical system 140 may include four to eight mirrors. However, the number of mirrors in the second optical system 140 are not necessarily limited to 4 to 8 and may be less than 4 or more than 8.

The second optical system 140 may transmit the EUV light reflected from the reticle R to the wafer W through reflection of the mirrors 141.

The reticle R may be disposed on the reticle stage 130. The reticle stage 130 may move along an x direction and along a y direction on an x-y plane and may move along a z direction that is perpendicular to the x-y plane. In addition, the reticle stage 130 may rotate about a z-axis, an x-axis, or a y-axis. Due to this movement and rotation of the reticle stage 130, the reticle stage 130 may move along the x direction, along the y direction, or along the z direction, and may rotate about the x-axis, the y-axis, or the z-axis.

Meanwhile, the reticle stage 130 may move along the y direction during an exposure process.

The reticle stage 130 may fix the reticle stage 130 by electrostatic force or vacuum adsorption. Accordingly, the reticle stage 130 may include elements corresponding to an electrostatic chuck or a vacuum chuck.

The wafer W, which is the EUV exposure target, may be disposed on the wafer stage 150. The wafer stage 150 may move along the x direction and along the y direction on the x-y plane and may move along the third direction (z direction) that is perpendicular to the x-y plane. In addition, the wafer stage 150 may rotate about the z-axis, the x-axis, or the y-axis. Due to this movement and rotation of the wafer stage 150, the wafer W may move along the x direction, along the y direction, or along the z direction, and may rotate about the x-axis, the y-axis, or the z-axis.

During the exposure process, the wafer stage 150 may move along a first direction (x direction) or along a second direction (y direction). In addition, the reticle stage 130 may move along a third direction (y direction) during the exposure process. The third direction may be the same second direction (y direction). During the exposure process, the reticle stage 130 may move along a direction that is parallel to a movement direction of the wafer stage 150 along the y direction, and the reticle stage 130 and the wafer stage 150 may move in opposite directions along the y direction.

FIG. 2 is a configuration diagram schematically illustrating another embodiment of the exposure device 100 in FIG. 1. To the extent that an element has not been described in detail, it may be assumed that the element is at least similar to corresponding elements that have been described in previous figures.

Referring to FIG. 3, an exposure device 200, according to another embodiment, may include an illumination source 210, a reticle stage 240, a transparent optical system 220, and a wafer stage 250.

The exposure device 200 shown in FIG. 3 is different from the exposure device 100 in FIG. 2 in that the exposure device 100 is a transmissive scanner and the exposure device 200 is a reflective scanner.

For example, the exposure device 200 shown in FIG. 3 differs from the exposure device 100 in FIG. 2 with respect to the scanning method. In the exposure device 100, the reticle stage 240 on which the reticle R is disposed is positioned between the illumination source 210 and the wafer stage 250 so that light generated by the illumination source 210 passes through the reticle R and is irradiated to the wafer W, whereas in the exposure device 200, the EUV light output from the UV source 110 is reflected from the reticle R and transferred to the wafer W.

The illumination source 210 may generate light having a certain wavelength. The illumination source 210 may generate deep ultra violet (DUV) light. Light generated by the illumination source 210 may be scanned to the reticle R mounted on the reticle stage 240, which is positioned under the illumination source 210.

In this case, the reticle R is mounted and fixed on the reticle stage 240 and driven along the second direction (y direction), so that the light from the illumination source 210 may transfer a thin-film pattern formed on the reticle R to a lower portion of the reticle R.

The transparent optical system 220 for reducing and projecting light that has passed through the reticle R may be installed under the reticle stage 240 on which the reticle R is fixed, wherein the reticle R is driven in one direction with respect to the fixed illumination source 210 and transfers a thin-film pattern.

The wafer stage 250 may be installed under the transparent optical system 220. The wafer stage 250 may be driven along the first direction (x direction) or along the second direction (y direction) during the exposure process. For example, when light is irradiated from a shot area of the wafer W, the wafer stage 250 and the reticle stage 240 may be driven in a forward direction or in a reverse direction along the second direction (y direction) so that light passing through the illumination source 210, the reticle stage 240, and the transparent optical system 220 may be exposed to the shot area of the wafer W by using a scanning method.

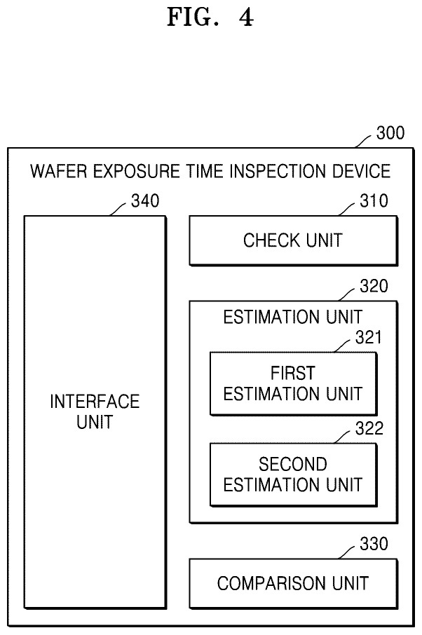

FIG. 4 is a configuration diagram schematically illustrating the wafer exposure time inspection device 300 in FIG. 1.

Referring to FIG. 4, the wafer exposure time inspection device 300 according to an embodiment may include a check circuit 310, an estimation circuit 320, a comparison circuit 330, and an interface circuit 340.

The check circuit 310 and the interface circuit 340 may be a processors or a comparators. The check circuit 310 may identify whether an exposure speed is set in the exposure device 100. Exposure may be performed by scanning the shot area along the second direction (y direction). The exposure speed is a speed at which exposure occurs in the shot area. The exposure speed in the shot area may be constant. An operator of the exposure device 100 may designate exposure speed as a specific speed or within a designated speed range. The check circuit 310 may identify whether the exposure speed of the exposure device 100 is designated as a certain speed or as a certain range.

The estimation circuit 320 may be embodied as a processor, wherein each of the specified circuits constitutes a component of that processor, each with its set of corresponding instructions. The estimation circuit 320 may model each of displacement of the wafer stage 150 of the exposure device 100 along the first direction (x direction), displacement of the wafer stage 150 along the second direction (y direction), and displacement of the reticle stage 130 along the third direction (z direction) as an equivalent snap motion and estimate a minimum step time or an optimal exposure speed. The modeling of the equivalent snap motion may be at least a third-order system modeling based on time for displacement. This is described below.

The first direction in which the wafer stage 150 moves may be the x direction on the xy plane, and the second direction in which the wafer stage 150 moves may be the y direction on the xy plane. The wafer stage 150 may move along the first direction (x direction), and in the second direction (y direction) on the x-y plane during the exposure process.

The third direction in which the reticle stage 130 moves may be the y direction on the x-y plane. For example, the third direction may be the same y direction as the second direction. During the exposure process, the reticle stage 130 may move in the third direction, which is the y direction, on the x-y plane.

Exposure of one shot area may be performed while the wafer stage 150 and the reticle stage 130 move at a constant speed in parallel or opposite directions with respect to the y direction.

The estimation circuit 320 may estimate a minimum step time for the exposure device 100 to transition to the next shot area on the wafer, minimizing the time between exposures. In addition, the estimation circuit 320 may estimate the optimal exposure speed that minimizes the sum of the step time and the scan time for exposing the shot area.

The estimation circuit 320 may include, for example, a first estimation circuit 321 and a second estimation circuit 322.

When the check circuit 310 identifies that the exposure speed is set to a certain value, the first estimation circuit 321 may estimate a minimum step time. When the check circuit 310 identifies that the exposure speed is set to a certain range, the second estimation circuit 322 may calculate an optimal exposure speed.

The exposure time of one shot area may be the sum of a step time to complete exposure to one shot area and move to the next shot area and a scan time to expose the shot area. Because exposure or scanning of a shot area is performed at a constant speed, when the exposure speed is determined by setting in the exposure device 100, the scan time may be calculated based on the set exposure speed. Accordingly, the long or short exposure time of the shot area may be determined by the step time. For example, the minimum exposure time of the shot area may be determined by the minimum step time.

The first estimation circuit 321 may estimate a minimum step time when the exposure speed is determined as a certain value as described above, and the comparison circuit 330 may derive a wafer exposure time from the minimum step time and a scan time according to a determined exposure speed and compare the derived wafer exposure time with a measured wafer exposure time, so as to evaluate appropriateness of the wafer exposure time of the exposure equipment 1000. This is described below. The comparison circuit 330 may be a processor or a comparator.

When the check circuit 310 identifies that the exposure speed is set to a certain range, the second estimation circuit 322 may calculate an optimal exposure speed.

When the exposure speed is determined to a certain range by setting the exposure device 100, the scan time may vary depending on the exposure speed within the range, and the step time may also change. Because the exposure speed is constant, the scan time decreases as the exposure speed increases. However, because the speed changes in a step section between adjacent shot areas, the step time does not decrease uniformly even when the exposure speed increases, and may increase or decrease within a certain range of the exposure speed.

When the exposure speed is determined as a certain range as described above, the second estimation circuit 322 may calculate an optimal exposure speed at which the scan time and the step time are minimized, and from the optimal exposure speed, the comparison circuit 330 may derive a wafer exposure speed and compare the derived wafer exposure speed with a measured wafer exposure time, so as to evaluate appropriateness of the wafer exposure time. This is described below.

For example, when the exposure speed is determined as a certain value, the first estimation circuit 321 may calculate a minimum step time (tᵢ^{step}) by using the equation (1) shown below.

$${t}_{i}^{step} = max ( {t}_{i}^{step . x} , {t}_{i}^{step . y} , {t}_{i}^{s tep . r} , minStepTime , min 1 ShotTime - \frac{D}{\vert {v}_{i} \vert} ) \qquad Equation ( 1 )$$

Here, a t₁^{step.x} is a minimum step time along a first direction for which the wafer stage 150 moves along a first direction in a section in which exposure to an (i−1)^{th} shot area is completed and the exposure device moves to expose an i^{th} shot area. Here, tᵢ^{step.y} is a minimum step time in a second direction for which the wafer stage 150 moves along the second direction in the section in which exposure to the (i−1)^{th} shot area is completed and the exposure device moves to expose the i^{th} shot area. A tᵢ^{step.r} is a minimum step time along a third direction for which the reticle stage 130 moves along the third direction in the section in which exposure to the (i−1)^{th} shot area is completed and the exposure device moves to expose the i^{th} shot area. Here, minStepTime is a set minimum step time that is input to the exposure device 100, min1ShotTime is a set minimum one-shot time that is input to the exposure device 100, Dᵢ is an exposure area length of the i^{th} shot area in the second direction, and vᵢ is the set exposure speed. One-shot time is the sum of an exposure time (scan time) and a step time for one shot area.

For example, the first estimation circuit 321 may estimate a minimum step time (tᵢ^{step}) by determining a maximum value from among the minimum step time (tᵢ^{step.x}) along the first direction for exposure of the wafer stage 150 in the i^{th} shot area, the minimum step time (tᵢ^{step.y}) along the second direction for exposure of the wafer stage 150 in the i^{th} shot area, the minimum step time (tᵢ^{step.r}) along the third direction for exposure of the reticle stage 130 in the i^{th} shot area, a set minimum step time input to the exposure device 100, and a step time obtained from a set minimum one-shot time input to the exposure device 100 and a scan time obtained by a set exposure speed. A one-shot time may be the sum of a scan time and a step time for one shot area, and a set minimum one-shot time may be a value set externally to the exposure device 100.

The first estimation circuit 321 may calculate the minimum step time (tᵢ^{step.x}) along the first direction for exposure of the wafer stage 150 to the i^{th} shot area by using Equation (2) shown below.

$${t}_{i}^{s tep . x} = {T}_{x} ( {x}_{i} , max . v e l . x , max . a c c . x , max . jerk . x , max . s nap . x , {T}_{s . w} ) \qquad Equation ( 2 )$$

The first estimation circuit 321 may calculate the minimum step time (tᵢ^{step.y}) along the second direction for exposure of the wafer stage 150 to the i^{th} shot area by using Equation (3) shown below.

$${t}_{i}^{step . y} = {T}_{y} ( {y}_{i} , {v}_{i - 1} , {v}_{i} , max . vel . y , max , acc . y , max . jerk . y , max . snap . y , {T}_{s . w} ) \qquad Equation ( 3 )$$

The first estimation circuit 321 may calculate the minimum step time (tᵢ^{step.r}) along the third direction for exposure of the reticle stage 130 to the i^{th} shot area by using Equation (4) shown below.

$${t}_{i}^{step . r} = {T}_{y} ( {r}_{i} , k {v}_{i - 1} , k {v}_{i} , max . ve l . r , max . acc . r , max . jerk . r , max . s nap . r , {T}_{s . r} ) \qquad Equation ( 4 )$$

Here, Tₓ may be a time model for movement of the wafer stage along the first direction, and T_{y} may be a time model for movement of the wafer stage or the reticle stage along the second direction. For example, Tₓ may be an equivalent snap motion model for displacement and speed changes along the x direction, and T_{y} may be an equivalent snap motion model for displacement and speed changes along the y direction. In the inventive step, a time model for movement along the third direction (y direction) of the reticle stage 130 as well as a movement along the first direction (x direction) and the second direction (y direction) of the wafer stage 150 is modeled at 3rd order or more so that estimation accuracy of step time may be improved.

xᵢ may be a distance that the wafer stage 150 moves along the first direction between an end position of exposure for the (i−1)^{th} shot area and a start position of exposure for the i^{th} shot area, yᵢ may be a distance that the wafer stage 150 moves along the second direction between the end position of exposure for the (i−1)^{th} shot area and the start position of exposure for the i^{th} shot area, and rᵢ may be a distance that the reticle stage 130 moves along the third direction between the end position of exposure for the (i−1)^{th} shot area and the start position of exposure for the i^{th} shot area.

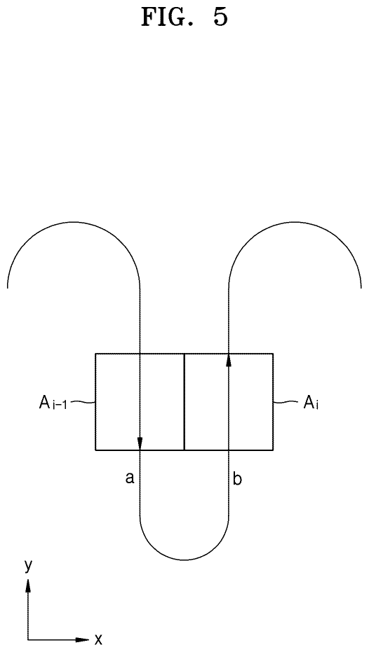

FIG. 5 is a diagram illustrating a movement trajectory of a wafer stage. Referring to FIG. 5, the exposure process may proceed with exposure along the −y direction for the shot area Aᵢ₋₁ on the wafer and along the +y direction for another shot area Aᵢ adjacent to the x direction.

xᵢ may be a distance that the wafer stage 150 moves along the first direction (x direction) between an end position of exposure for the (i−1)^{th} shot area Aᵢ₋₁ and a start position b of exposure for the i^{th} shot area Aᵢ.

yᵢ may be a distance that the wafer stage 150 moves along the second direction (y direction) between the end position a of exposure for the (i−1)^{th} shot area Aᵢ₋₁ and the start position b of exposure for the i^{th} shot area Aᵢ. Because the end position a of exposure for the (i−1)^{th} shot area Aᵢ₋₁ and the start position b of exposure for the i^{th} shot area Aᵢ are the same along the y direction, yᵢ may be 0.

When considering a margin, the end position a and start position b of exposure may be spaced apart from a boundary of the shot areas (Aᵢ and Aᵢ₋₁) to the outside at a certain distance.

T_{s.w} may be a settling time of the wafer stage 150. The wafer stage 150 may maintain a constant speed in the shot area Aᵢ, and reach a constant exposure speed before arriving at the exposure time b of the shot area Aᵢ.

T_{s.r} may be a settling time of the reticle stage 130 and may be a time at which the reticle stage 130 reaches a constant exposure speed.

vᵢ₋₁ may be an exposure speed in the (i−1)^{th} shot area Aᵢ₋₁, vᵢ may be an exposure speed in the i^{th} shot area Aᵢ, max.vel.x may be a maximum speed of the wafer stage 150 along the first direction, max.acc.x may be a maximum acceleration of the wafer stage 150 along the first direction, max.jerk.x may be a maximum jerk of the wafer stage 150 in the first direction, and max.snap.x may be a maximum snap of the wafer stage 150 in the first direction. Here, acceleration is a first derivative of velocity, jerk is a second derivative of velocity, and snap is a third derivative of velocity.

max.vel.y may be a maximum speed of the wafer stage 150 along the second direction, max.acc.y may be a maximum acceleration of the wafer stage 150 along the second direction, max.jerk.y may be a jerk of the wafer stage 150 along the second direction, and max.snap.y may be a maximum snap of the wafer stage 150 along the second direction.

max.vel.r may be a maximum speed of the reticle stage 130 along the third direction, max.acc.r may be a maximum acceleration of the reticle stage 130 along the third direction, max.jerk.r may be a maximum jerk of the reticle stage 130 along the third direction, and max.snap.r is a maximum snap of the reticle stage 130 along the third direction.

k may be an exposure ratio. For example, the exposure ratio k may be 4.

There may be constraints on the movement trajectory of the wafer stage 150. For example, when performing liquid immersion exposure, constraints may be placed on the movement trajectory of the wafer stage 150 and reduce exposure defects on the outside of the wafer. The wafer stage 150 may interact with each other when moving along the x direction and along the y direction. For example, movement of the wafer stage 150 along the x direction may affect movement of the wafer stage 150 along the y direction, and movement along the y direction may affect movement along the x direction.

In this case, the first estimation circuit 321 may estimate the minimum step time tᵢ^{step} by using Equation (1) shown below.

$${t}_{i}^{step} max ( {t}_{i}^{step . xy} , {t}_{i}^{s tep . r} , minStepTime , min 1 ShotTime - \frac{{D}_{i}}{\vert {v}_{i} \vert} ) \qquad Equation ( 5 )$$

Here, tᵢ^{step.xy} may be a limited minimum step time for the movement of the wafer stage 150 along its trajectory, for example in the section where exposure of the (i−1)^{th} shot area Aᵢ₋₁ concludes and the exposure device transitions to expose the i^{th} shot area Aᵢ.

tᵢ^{step,r} may be a minimum step time for the reticle stage 130 to move along the third direction in the section where exposure of the (i−1)^{th} shot area Aᵢ₋₁ concludes and the exposure device moves to expose the i^{th} shot area Aᵢ. minStepTime is a predetermined minimum one-shot time input to the exposure device. Dᵢ is a length of the exposure area of the shot area along the second direction. vᵢ may be the predetermined exposure speed.

The first estimation circuit 321 may calculate the limited minimum step time tᵢ^{step.xy} by using Equation (6) shown below:

$${t}_{i}^{s tep . xy} = {T}_{x y} ( {x}_{i c . i} , {y}_{i c . i} , {x}_{fc . i} , {y}_{fc . i} , {v}_{i - 1} , {v}_{i} , max . vel . x , max . acc . x , max . jerk . x , max . snap . x , max . vel . y , max . acc . y , max . jerk . y , max . snap . y , {T}_{s . w} , C ) \qquad Equation ( 6 )$$

tᵢ^{step,r} is obtained by using Equation (7) shown below:

Tᵢ^{step.r}=T_{y}(rᵢ,kvᵢ₋₁,kvᵢ, max.vel.r, max.acc.r, max.jerk.r, max.snap.r,T_{s.r}) Equation (7)

Here, T_{xy} may be a time model for the movement trajectory, x_{ic.i} and y_{ic.i} may be starting positions of exposure for the i^{th} shot area Aᵢ, x_{fc.i} and y_{fc.i} may be end positions of exposure for the i^{th} shot area Aᵢ, vᵢ₋₁ may be an exposure speed in the shot area Aᵢ₋₁, vᵢ may be an exposure speed in the i^{th} shot area, and T_{s.w} may be a settling time of the wafer stage 150.

max.vel.x may be a maximum speed of the wafer stage 150 along the first direction, max.acc.x may be a maximum acceleration of the wafer stage 150 along the first direction, max.jerk.x may be a jerk of the wafer stage 150 along the first direction, and max.snap.x may be a maximum snap of the wafer stage 150 along the first direction.

max.vel.y may be a maximum speed of the wafer stage 150 along the second direction, max.acc.y may be a maximum acceleration of the wafer stage 150 along the second direction, max.jerk.y may be a jerk of the wafer stage 150 along the second direction, and max.snap.y may be a maximum snap of the wafer stage 150 along the second direction.

max.vel.r may be a maximum speed of the reticle stage 130 along the third direction, max.acc.r may be a maximum acceleration of the reticle stage 130 along the third direction, max.jerk.r may be a maximum jerk of the reticle stage 130 along the third direction, and max.snap.r may be a maximum snap of the reticle stage 130 along the third direction.

k is an exposure ratio, and C is a constant indicating a defect constraint condition according to movement trajectory limitation.

When the exposure speed is set to a certain range as described above, the second e estimation circuit 322 may estimate an optimal exposure speed sᵢ* in which the scan time and the step time are minimized by using Equation (8) and Equation (9) shown below:

$${s}_{i}^{*} = \begin{matrix}arg min \\ {s}_{i} ∈ \{ {s}_{m . i} , {s}_{i}^{y} , {s}_{i}^{r} , {s}_{i}^{1} , {s}_{i}^{0} , {s}_{M . i} \}\end{matrix} f ( {s}_{i} ) \qquad Equation ( 8 )$$

$${f ( {s}_{i} ) = \frac{{D}_{i}}{{s}_{i}} + {t}_{i}^{step} \vert}_{{v}_{i} = {s}_{i} , {v}_{i - 1} = - {s}_{i} , {y}_{i} = 0 , {r}_{i} = 0} \qquad Equation ( 9 )$$

Here, f(sᵢ) may be an exposure time for the i^{th} shot area Aᵢ, Dᵢ may be an exposure area length of the i^{th} shot area Aᵢ along the second direction (y direction), sᵢ may be an exposure speed, and tᵢ^{step} may be a minimum step time. The minimum step time tᵢ^{step} may be a step time in a case in which the exposure speed in the (i−1)^{th} shot area Aᵢ₋₁ and the exposure speed in the i^{th} shot area Aᵢ are the same in size but in opposite directions, and the displacement of the wafer stage 150 along the second direction (y direction) and the displacement of the reticle stage 130 along the third direction (y direction) are 0. In FIG. 5, the displacement of the wafer stage 150 along the second direction (y direction) and the displacement of the reticle stage 130 along the third direction (y direction) may be 0 in a step section, from a, which is the scan end point of the (i−1)^{th} shot area Aᵢ₋₁, and b, which is the scan start time of the i^{th} shot area Aᵢ. For example, the minimum step time tᵢ^{step} may be a step time in the step section between point a and point b in FIG. 5.

s_{m.i} may be a minimum exposure speed at which exposure for the i^{th} shot area Aᵢ is possible, and s_{M.i} may be a maximum exposure speed at which exposure for the i^{th} shot area Aᵢ is possible. s_{m.i} and s_{M.i} may be respectively the minimum exposure speed and the maximum exposure speed that are determined by exposure conditions, such as a shape of a reticle pattern to be transferred or the energy of light generated by the exposure device 100.

sᵢ^{y} is shown in the Equation (10), sᵢ^{r} is Equation (11), and sᵢ¹ is shown in Equation (12).

$${s}_{i}^{y} = max ( min ( \sqrt{\frac{{D}_{i} max . acc . y}{2}} , {s}_{M . i} ) , {s}_{my . i} ) \qquad Equation ( 10 )$$

$${s}_{i}^{r} = max ( min ( \sqrt{\frac{{D}_{i} max . acc . r}{2 k}} , {s}_{M . i} ) , {s}_{mr . i} ) \qquad Equation ( 11 )$$

$${s}_{i}^{1} = \frac{{D}_{i}}{min 1 ShotTime - {t}_{i}^{s tep . x}} \qquad Equation ( 12 )$$

Here, s_{my.1} may be an optimal exposure speed along the second direction at which the wafer stage 150 moves along the second direction in the i^{th} shot area A₁. The optimal exposure speed occurs when tᵢ^{step.x}, a minimum step time for the wafer stage 150 to move along the first direction (x direction) after completing exposure for the (i−1)^{th} shot area and before the exposure device moves to expose is the same as tᵢ^{step.y}. The tᵢ^{step.y} is a minimum step time for movement along the second direction after completing exposure for the (i−1)^{th} shot area and before the exposure device moves to expose the i^{th} shot area A₁.

s_{mr.i} may be an optimal exposure speed along the third direction at which the reticle stage moves along the third direction in the i^{th} shot area. The optimal exposure speed occurs when the minimum step time t₁^{step.x} along the first direction is the same as tᵢ^{step.r}, tᵢ^{step.r} is a minimum step time for movement along the third direction by the reticle stage after completing exposure for the (i−1)^{th} shot area and before the exposure device moves to expose the i^{th} shot area.

The optimal exposure speed s_{my.1} along the second direction and the optimal exposure speed s_{mr.i} along the third direction may be within a range between the minimum exposure speed s_{m.i} at which exposure is possible and the maximum exposure speed s_{M.i} at which exposure is possible. However, when the optimal exposure speed s_{my.1} along the second direction and the optimal exposure speed s_{mr.i} along the third direction is out of the range between the minimum exposure speed s_{m.i} at which exposure is possible and the maximum exposure speed s_{M.i} at which exposure is possible, the optimal exposure speed s_{my.1} along the second direction and the optimal exposure speed s_{mr.i} along the third direction may be set to the maximum exposure speed s_{M.i} at which exposure is possible.

tᵢ^{step.x} is obtained by using Equation (13) shown below:

$${f}_{i}^{s tep . x} = {T}_{x} ( {x}_{i} , max . v e l . x , max . a c c . x , max . jerk . x , max . snap . x , {T}_{s . w} ) \qquad Equation ( 13 )$$

tᵢ^{step.y} is obtained by using Equation (14) shown below:

$${t}_{i}^{s tep . y} = {T}_{y} ( {y}_{i} , {s}_{My . i} , max . vel . y , max . acc . y , max . jerk . y , max . snap . y , {T}_{s . w} ) \qquad Equation ( 14 )$$

tᵢ^{step,r} is obtained by using Equation (15) shown below:

$${t}_{i}^{step . r} = {T}_{y} ( {r}_{i} , k {s}_{Mr . i} , max . vel . r , max . acc . r , max . jerk . r , max . snap . r , {T}_{s . r} ) \qquad Equation ( 15 )$$

Here, Tₓ may be a time model for movement of the wafer stage along the first direction, and T_{y} may be a time model for movement of the wafer stage or the reticle stage along the second direction. Tₓ may be an equivalent snap motion model for displacement along the x direction, and T_{y} may be an equivalent snap motion model for displacement along the y direction.

xᵢ may be a distance that the wafer stage 150 moves along the first direction (x direction) between the end position (a in FIG. 5) of exposure for the (i−1)^{th} shot area Aᵢ₋₁ and the start position (b in FIG. 5) of exposure for the i^{th} shot area Aᵢ. yᵢ may be a distance that the wafer stage 150 moves along the second direction (y direction) between the end position (a in FIG. 5) of exposure for the (i−1)^{th} shot area Aᵢ₋₁ and the start position (b in FIG. 5) of exposure for the i^{th} shot area Aᵢ. rᵢ may be a distance that the reticle stage 130 moves along the third direction (y direction) between the end position (a in FIG. 5) of exposure for the (i−1)^{th} shot area Aᵢ₋₁ and the start position (b in FIG. 5) of exposure for the i^{th} shot area Aᵢ.

T_{s.w} may be a settling time of the wafer stage 150, and T_{s.r} may be a settling time of the reticle stage 130.

s_{My.i} may be a maximum exposure speed in the i^{th} shot area Aᵢ along the second direction, max.vel.x may be a maximum speed of the wafer stage 150 along the first direction, max.acc.x may be a maximum acceleration of the wafer stage 150 along the first direction, max.jerk.x may be a maximum jerk of the wafer stage 150 along the first direction, and max.snap.x may be a maximum snap of the wafer stage 150 along the first direction.

max.vel.y may be a maximum speed of the wafer stage 150 along the second direction, max.acc.y may be a maximum acceleration of the wafer stage 150 along the second direction, max.jerk.y may be a jerk of the wafer stage 150 along the second direction, and max.snap.y may be a maximum snap of the wafer stage 150 along the second direction.

max.vel.r may be a maximum speed of the reticle stage 130 along the third direction, max.acc.r may be a maximum acceleration of the reticle stage 130 along the third direction, max.jerk.r may be a maximum jerk of the reticle stage 130 along the third direction, and max.snap.r may be a maximum snap of the reticle stage 130 in the third direction.

k may be an exposure ratio. For example, the exposure ratio k may be 4.

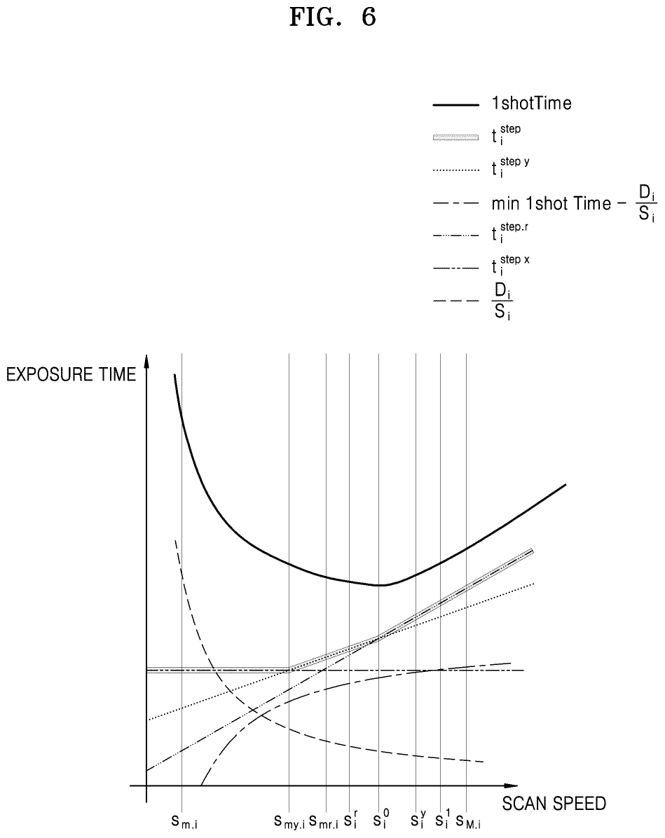

FIG. 6 is a graph showing a one-shot exposure time according to changes in exposure speed.

Referring to FIG. 6, the x-axis is exposure speed (scan speed), and the y-axis is one-shot exposure time. The one-shot exposure time is the sum of a scan time and a step time for one shot area. As described above, the scan time decreases as the exposure speed increases. However, because the speed changes in a step section between adjacent shot areas, the step time does not decrease uniformly even when the exposure speed increases, and may increase or decrease within a certain range of the exposure speed. This may be identified through a one-shot exposure time graph in FIG. 6. For example, when the exposure speed (scan speed) increases up to sᵢ⁰, the one-shot exposure time decreases, but when the exposure speed exceeds sᵢ⁰, the one-shot exposure time increases.

Within a range between the minimum exposure speed s_{m.i} at which exposure is possible and the maximum exposure speed s_{M.i} at which exposure is possible, s_{my.i}, s_{mr.i}, s₁^{r}, sᵢ⁰, sᵢ^{y}, and sᵢ¹ may be extreme points of the one-shot exposure time or boundary points where the time model switches. The second estimation circuit 322 may estimate a minimum exposure speed sᵢ* at which the one-shot exposure time at the extreme points or the boundary points is minimized.

The second estimation circuit 322 may divide shot areas of the wafer into a plurality of groups and may estimate the optimal exposure speed sᵢ* from among the exposure speeds for each group by using Equation (16) and Equation (17) shown below:

$${s}_{i}^{*} = \begin{matrix}arg min \\ {s}_{i} ∈ \{ {s}_{m . i} , {s}_{i}^{y} , {s}_{i}^{r} , {s}_{i}^{1} , {s}_{i}^{0} , {s}_{M . i} \}\end{matrix} f ( {s}_{i} ) \qquad Equation ( 16 )$$

$${{f}_{G} ( {s}_{i} ) = {\sum }_{i ∈ {G}_{j}} ( \frac{{D}_{i}}{{s}_{i}} + {t}_{i}^{s t e p} \vert}_{{v}_{i} = {d}_{i} \cdot {s}_{i} , {v}_{i - 1} = {d}_{( i - 1 )} \cdot {s}_{( i - 1 )}} ) \qquad Equation ( 17 )$$

Here, f_{G}(sᵢ) may be an exposure time for an i^{th} group, and Gⱼ may be a group obtained by dividing the shot areas. Dᵢ may be an exposure area length of the i^{th} shot area along the second direction, sᵢ may be an exposure speed in the shot area, dᵢ may be an exposure direction, and tᵢ^{step} may be the minimum step time.

s_{m.i} may be a minimum exposure speed at which exposure for the i^{th} shot area Aᵢ is possible, and s_{M.i} may be a maximum exposure speed at which exposure for the i^{th} shot area Aᵢ is possible. s_{m.i} and s_{M.i} may be respectively the minimum exposure speed and the maximum exposure speed that are determined by exposure conditions, such as a shape of a reticle pattern to be transferred or the energy of light generated by the exposure device 100.

sᵢ^{y} is shown in the Equation (18), sᵢ^{r} is Equation (19), and sᵢ¹ is shown in Equation (20).

$${s}_{i}^{y} = max ( min ( \sqrt{\frac{{D}_{i} max \cdot acc \cdot y}{2}} , {s}_{M \cdot i} ) , {s}_{my \cdot i} ) \qquad Equation ( 18 )$$

$${s}_{i}^{r} = max ( min ( \sqrt{\frac{{D}_{i} max \cdot acc \cdot r}{2 k}} , {s}_{M \cdot i} ) , {s}_{mr \cdot i} ) \qquad Equation ( 19 )$$

$${s}_{i}^{1} = \frac{{D}_{i}}{min 1 ShotTime - {t}_{i}^{step \cdot x}} \qquad Equation ( 20 )$$

Here, s_{my.1} may be an optimal exposure speed along the second direction at which the wafer stage 150 moves along the second direction in the i^{th} shot area A₁. The optimal exposure speed may occur when tᵢ^{step.x}, a minimum step time for the wafer stage 150 to move along the first direction (x-direction) after competing exposure for the (i−1)^{th} shot area and before the exposure device moves to expose the i^{th} shot area A₁, is the same as tᵢ^{step.y}. tᵢ^{step.y} is a minimum step time for movement along the second direction after the wafer stage 150 moves along the second direction in the section in which exposure for the (i−1)^{th} shot area is completed and before the exposure device moves to expose the i^{th} shot area A₁.

s_{mr.i} may be an optimal exposure speed along the third direction at which the reticle stage moves in the third direction in the i^{th} shot area, in a case in which the minimum step time tᵢ^{step.x} along the first direction is the same as tᵢ^{step.r}, which is a minimum step time in the third direction after the reticle stage moves along the third direction in the section in which exposure for the (i−1)th shot area is completed and after the exposure device moves to expose the i^{th} shot area.

The optimal exposure speed s_{my.1} along the second direction and the optimal exposure speed s_{mr.i} along the third direction may be within a range between the minimum exposure speed s_{m.i} at which exposure is possible and the maximum exposure speed s_{M.i} at which exposure is possible. However, when the optimal exposure speed s_{my.1} along the second direction and the optimal exposure speed s_{mr.i} along the third direction is out of the range between the minimum exposure speed s_{m.i} at which exposure is possible and the maximum exposure speed s_{M.i} at which exposure is possible, the optimal exposure speed s_{my.1} along the second direction and the optimal exposure speed s_{mr.i} along the third direction may be set to the maximum exposure speed s_{M.i} at which exposure is possible.

t₁^{step.x} is obtained by using Equation (21) shown below:

$${t}_{i}^{step \cdot x} = {T}_{x} ( {x}_{i} , max \cdot vel \cdot x , \\ max \cdot acc \cdot x , max \cdot jerk \cdot x , max \cdot snap \cdot x , {T}_{s \cdot w} ) \qquad Equation ( 21 )$$

tᵢ^{step.y} is obtained by using Equation (22) shown below:

$${t}_{i}^{step \cdot y} = {T}_{y} ( {y}_{i ,} , {s}_{My \cdot i} , max \cdot vel \cdot y , \\ max \cdot acc \cdot y , max \cdot jerk \cdot y , max \cdot snap \cdot y , {T}_{s \cdot w} ) \qquad Equation ( 22 )$$

tᵢ^{step,r} is obtained by using Equation (23) shown below:

$${t}_{i}^{step \cdot r} = {T}_{y} ( {r}_{i} , {ks}_{Mr \cdot i} , max \cdot vel \cdot r , \\ max \cdot acc \cdot r , max \cdot jerk \cdot r , max \cdot snap \cdot r , {T}_{s \cdot r} ) \qquad Equation ( 23 )$$

Here, Tₓ may be a time model for movement of the wafer stage along the first direction, and T_{y} may be a time model for movement of the wafer stage or the reticle stage along the second direction. Tₓ may be an equivalent snap motion model for displacement in the x direction, and T_{y} may be an equivalent snap motion model for displacement in the y direction.

xᵢ may be a distance that the wafer stage 150 moves along the first direction (x direction) between the end position (a in FIG. 5) of exposure for the (i−1)^{th} shot area Aᵢ₋₁ and the start position (b in FIG. 5) of exposure for the i^{th} shot area Aᵢ. yᵢ may be a distance that the wafer stage 150 moves along the second direction (y direction) between the end position (a in FIG. 5) of exposure for the (i−1)^{th} shot area Aᵢ₋₁ and the start position (b in FIG. 5) of exposure for the i^{th} shot area Aᵢ. rᵢ may be a distance that the reticle stage 130 moves along the third direction (y direction) between the end position (a in FIG. 5) of exposure for the (i−1)^{th} shot area Aᵢ₋₁ and the start position (b in FIG. 5) of exposure for the i^{th} shot area Aᵢ.

T_{s.w} may be a settling time of the wafer stage 150, and T_{s.r} may be a settling time of the reticle stage 130.

s_{My.i} may be a maximum exposure speed in the i^{th} shot area Aᵢ along the second direction, max.vel.x may be a maximum speed of the wafer stage 150 along the first direction, max.acc.x may be a maximum acceleration of the wafer stage 150 along the first direction, max.jerk.x may be a maximum jerk of the wafer stage 150 along the first direction, and max.snap.x may be a maximum snap of the wafer stage 150 along the first direction.

max.vel.y may be a maximum speed of the wafer stage 150 along the second direction, max.acc.y may be a maximum acceleration of the wafer stage 150 along the second direction, max.jerk.y may be a jerk of the wafer stage 150 along the second direction, and max.snap.y may be a maximum snap of the wafer stage 150 along the second direction.

max.vel.r may be a maximum speed of the reticle stage 130 along the third direction, max.acc.r may be a maximum acceleration of the reticle stage 130 along the third direction, max.jerk.r may be a maximum jerk of the reticle stage 130 along the third direction, and max.snap.r may be a maximum snap of the reticle stage 130 along the third direction.

k may be an exposure ratio. For example, the exposure ratio k may be 4.

The comparison circuit 330 may compare a measured wafer exposure time with a first optimal wafer exposure time calculated from a minimum step time and a scan time, the minimum step time being calculated by the first estimation circuit 321. In addition, the comparison circuit 330 may compare the measured wafer exposure time with a second optimal wafer exposure time calculated from an optimal exposure speed estimated by the second estimation circuit 322.

The comparison circuit 330 may evaluate appropriateness of the measured exposure time by comparing the calculated first and second optimal wafer exposure times with the measured wafer exposure time. For example, when a difference between the calculated first and second optimal wafer exposure times with the measured wafer exposure time exceeds a certain range, the comparison circuit 330 may determine that an exposure process of the exposure device 100 is inappropriate. The comparison circuit 330 may present the minimum step time estimated by the first estimation circuit 321 and the optimal exposure speed estimated by the second estimation circuit 322, and apply the minimum step time or the optimal exposure speed so that a wafer exposure time of the exposure device 100 may be improved.

The comparison circuit 330 may compare the minimum step time estimated by the first estimation circuit 321 with the measured step time, calculate an optimal wafer exposure time from the minimum step time with the scan time, and compare the optimal wafer exposure time with the measured wafer exposure time.

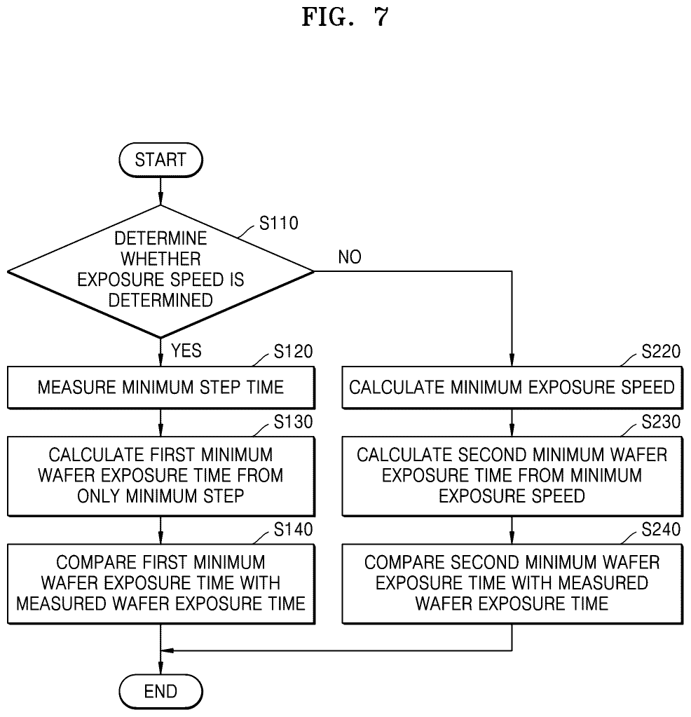

FIG. 7 is a flowchart of a method of inspecting a wafer exposure time, according to an embodiment.

Referring to FIG. 7, the check circuit 310 may identify whether an exposure speed is set in the exposure device 100, in operation S110. The exposure speed may be designated by an operator of the exposure device 100 as a certain speed or may be designated as a certain speed range. The check circuit 310 may identify whether the exposure speed of the exposure device 100 is designated as a certain speed or as a certain range.

Next, when the check circuit 310 identifies that the exposure speed is set to a certain value (Yes), the first estimation circuit 321 may estimate a minimum step time, in operation S120. When the check circuit 310 identifies that the exposure speed is set to a certain range (No), the second estimation circuit 322 may calculate an optimal exposure speed, in operation S220.

Next, when the exposure speed is set to a certain value, the first estimation circuit 321 may estimate a first minimum step time, in operation S130, and when it is identified that the exposure speed is set to a certain range, the second estimation circuit 322 may calculate an optimal exposure speed, in operation S230.

Next, the comparison circuit 330 may compare a measured wafer exposure time with a first optimal wafer exposure time calculated from the minimum step time calculated by the first estimation circuit 321 and a scan time, in operation S140. In addition, the comparison circuit 330 may compare the measured wafer exposure time with a second optimal wafer exposure time calculated from the optimal exposure speed estimated by the second estimation circuit 322, in operation S240.

While the inventive concept has been particularly shown and described with reference to embodiments thereof, it will be understood that various changes in form and details may be made therein without departing from the spirit and scope of the present disclosure.

What is claimed is:

1. Exposure equipment comprising:
an exposure device configured to transfer a pattern of a reticle to a wafer by using light; and
a wafer exposure time inspection device configured to inspect appropriateness of a wafer exposure time during which the wafer is illuminated to transfer the pattern to the wafer,
wherein the wafer exposure time inspection device comprises:
an estimation unit configured to estimate a minimum step time or an optimal exposure speed, wherein, in the minimum step time, a step time during which an exposure device completes exposure for one shot area from among a plurality of shot areas on a wafer and moves to a next shot area is minimized, and in the optimal exposure speed, a sum of the step time and a scan time during which the shot area is exposed is minimized; and
a comparison unit configured to compare a measured wafer exposure time with a first optimal wafer exposure time calculated from the minimum step time and the scan time or compare the measured wafer exposure time with a second optimal wafer exposure time calculated from the estimated optimal exposure speed,
wherein the optimal wafer exposure time is a time during which a wafer exposure time is minimized, the wafer exposure time being a sum of a scan time for exposure for each of all shot areas of the wafer with a step time for movement between the shot areas.

2. The exposure equipment of claim 1, wherein the estimation unit is further configured to estimate the minimum step time or the optimal exposure speed by modeling, by using at least a 3rd-order system, a time model for each of a displacement of a wafer stage of the exposure device in a first direction, a displacement of the wafer stage in a second direction, and a displacement of a reticle stage in a third direction, and
the first direction is perpendicular to the second direction in which the shot area is exposed, and the third direction is parallel to the second direction.

3. The exposure equipment of claim 2, further comprising a check unit configured to identify whether an exposure speed is set in the exposure device.

4. The exposure equipment of claim 3, wherein the estimation unit comprises a first estimation unit and a second estimation unit,
when it is identified by the check unit that the exposure speed is set to a certain value, the first estimation unit is configured to estimate the minimum step time, and
when it is identified by the check unit that the exposure speed is set to a certain range, the second estimation unit is configured to calculate the optimal exposure speed.

5. The exposure equipment of claim 4, wherein the first estimation unit is further configured to estimate a minimum step time tᵢ^{step} by using Equation (1):
$${t}_{i}^{step} = max ( {t}_{i}^{step \cdot x} , {t}_{i}^{step \cdot y} , {t}_{i}^{step \cdot r} , min StepTime , min 1 ShotTime - \frac{{D}_{i}}{\vert {v}_{i} \vert} ) , \qquad Equation ( 1 )$$
wherein t₁^{step.x} is a minimum step time in the first direction during which the wafer stage moves in the first direction in a section in which exposure for an (i−1)^{th} shot area Aᵢ₋₁ is completed and the exposure device moves to expose an i^{th} shot area, tᵢ^{step.y} is a minimum step time in the second direction during which the wafer stage moves in the second direction in a section in which exposure for the (i−1)^{th} shot area is completed and the exposure device moves to expose the i^{th} shot area, tᵢ^{step,r} is a minimum step time in the third direction during which the reticle stage moves in the third direction in a section in which exposure for the (i−1)^{th} shot area Aᵢ₋₁ is completed and the exposure device moves to expose the i^{th} shot area, minStepTime is a set minimum step time that is input to the exposure device, min1ShotTime is a set minimum one-shot time that is input to the exposure device, Dᵢ is an exposure area length of the i^{th} shot area in the second direction, and vᵢ is the exposure speed that is set,
t₁^{step.x} is obtained by using Equation (2):
$${t}_{i}^{step \cdot x} = {T}_{x} ( {x}_{i} , max \cdot vel \cdot x , \\ max \cdot acc \cdot x , max \cdot jerk \cdot x , max \cdot snap \cdot x , {T}_{s \cdot w} ) , \qquad Equation ( 2 )$$
tᵢ^{step.y} is obtained by using Equation (3):
$${t}_{i}^{step \cdot y} = {T}_{y} ( {y}_{i ,} {v}_{i - 1} , {v}_{i} , max \cdot vel \cdot y , \\ max \cdot acc \cdot y , max \cdot jerk \cdot y , max \cdot snap \cdot y , {T}_{s \cdot w} ) , \qquad Equation ( 3 )$$
tᵢ^{step.r} is obtained by using Equation (4):
$${t}_{i}^{step \cdot r} = {T}_{y} ( {r}_{i} , {kv}_{i - 1} , {kv}_{i} , max \cdot vel \cdot r , \\ max \cdot acc \cdot r , max \cdot jerk \cdot r , max \cdot snap \cdot r , {T}_{s \cdot r} ) , \qquad Equation ( 4 )$$
wherein Tₓ is a time model for movement of the wafer stage in the first direction, T_{y} is a time model for movement of the wafer stage or the reticle stage in the second direction, xᵢ is a distance the wafer stage moves in the first direction between an end position of exposure for the (i−1)^{th} shot area and a start position for the i^{th} shot area, yᵢ is a distance the wafer stage moves in the second direction between the end position of exposure for the (i−1)^{th} shot area and the start position for the i^{th} shot area, rᵢ is a distance the reticle stage moves in the third direction between the end position of exposure for the (i−1)^{th} shot area and the start position for the i^{th} shot area, T_{s.w} is a settling time of the wafer stage, T_{s.r} is a settling time of the reticle stage, vᵢ₋₁ is an exposure speed is an exposure speed in the (i−1)^{th} shot area, vᵢ is an exposure speed in the i^{th} shot area, max.vel.x is a maximum speed of the wafer stage in the first direction, max.acc.x is a maximum acceleration of the wafer stage in the first direction, max.jerk.x is a maximum jerk of the wafer stage in the first direction, max.snap.x is a maximum snap of the wafer stage in the first direction, max.vel.y is a maximum speed of the wafer stage in the second direction, max.acc.y is a maximum acceleration of the wafer stage in the second direction, max.jerk.y is a maximum jerk of the wafer stage in the second direction, max.snap.y is a maximum snap of the wafer stage in the second direction, max.vel.r is a maximum speed of the reticle stage in the third direction, max.acc.r is maximum acceleration of the reticle stage in the third direction, max.jerk.r is a maximum jerk of the reticle stage in the third direction, max.snap.r is a maximum snap of the reticle stage in the third direction, and k is an exposure ratio.

6. The exposure equipment of claim 4, wherein, when constraints are applied on a movement trajectory of the wafer stage,
the first estimation unit is further configured to estimate a minimum step time tᵢ^{step} by using Equation (1):
$${t}_{i}^{step} = max ( {t}_{i}^{step \cdot xy} , {t}_{i}^{step \cdot r} , min StepTime , min 1 ShotTime - \frac{{D}_{i}}{\vert {v}_{i} \vert} ) , \qquad Equation ( 5 )$$
wherein t; step.xy is a limited minimum step time during which the wafer stage moves along the movement trajectory in a section in which exposure for an (i−1)^{th} shot area is completed and the exposure device moves to expose an i^{th} shot area, tᵢ^{step,r} is a minimum step time in the third direction during which the reticle stage moves in the third direction in a section in which exposure for the (i−1)^{th} shot area is completed and the exposure device moves to expose the i^{th} shot area, minStepTime is a set minimum step time input to the exposure device, min1ShotTime is a set minimum one-shot time input to the exposure device, Dᵢ is an exposure area length of the shot area in the second direction, and vᵢ is the exposure speed that is set,
tᵢ^{step.xy} is obtained by using Equation (6):
$${t}_{i}^{step \cdot xy} = {T}_{xy} ( {x}_{ic \cdot i} , {y}_{ic \cdot i} , {x}_{fc \cdot i} , {y}_{fc \cdot i} , {v}_{i - 1} , {v}_{i} , max \cdot vel \cdot x , \\ max \cdot acc \cdot x , max \cdot jerk \cdot x , max \cdot snap \cdot x , max \cdot vel \cdot y , \\ max \cdot acc \cdot y , max \cdot jerk \cdot y , max \cdot snap \cdot y , {T}_{s \cdot w} , C ) , \qquad Equation ( 6 )$$
and
tᵢ^{step.r} is obtained by using Equation (7) shown below:
$${t}_{i}^{step \cdot r} = {T}_{y} ( {r}_{i} , {kv}_{i - 1} , {kv}_{i} , max \cdot vel \cdot r , \\ max \cdot acc \cdot r , max \cdot jerk \cdot r , max \cdot snap \cdot r , {T}_{s \cdot r} ) , \qquad Equation ( 7 )$$
wherein T_{xy} is a time model for the movement trajectory, x_{ic.i} and y_{ic.i} are start positions of exposure for the i^{th} shot area, x_{fc.i} and x_{fc.i} are end positions of exposure for the i^{th} shot area, vᵢ₋₁ is an exposure speed in the (i−1)^{th} shot area, vᵢ is an exposure speed in the i^{th} shot area, T_{s.w} is a settling time of the wafer stage, max.vel.x is a maximum speed of the wafer stage in the first direction, max.acc.x is a maximum acceleration of the wafer stage in the first direction, max.jerk.x is a maximum jerk of the wafer stage in the first direction, max.snap.x is a maximum snap of the wafer stage in the first direction, max.vel.y is a maximum speed of the wafer stage in the second direction, max.acc.y is a maximum acceleration of the wafer stage in the second direction, max.jerk.y is a maximum jerk of the wafer stage in the second direction, max.snap.y is a maximum snap of the wafer stage in the second direction, max.vel.r is a maximum speed of the reticle stage in the third direction, max.acc.r is a maximum acceleration of the reticle stage in the third direction, max.jerk.r is a maximum jerk of the reticle stage in the third direction, max.snap.r is a maximum snap of the reticle stage in the third direction, k is an exposure ratio, and C is a defect constraint condition.

7. The exposure equipment of claim 4, wherein the second estimation unit is further configured to estimate the optimal exposure speed (sᵢ*) by using Equation (8) and Equation (9):
$${s}_{i} *= \begin{matrix}arg min \\ {s}_{i} ∈ \{ {s}_{m \cdot i} , {s}_{i}^{y} , {s}_{i}^{r} , {s}_{i}^{1} , {s}_{i}^{0} , {s}_{M \cdot i} \}\end{matrix} f ( {s}_{i} ) , \qquad Equation ( 8 )$$
$$f ( {s}_{i} ) = \frac{{D}_{i}}{{s}_{i}} + {t}_{i}^{step} {\vert}_{{v}_{i} = {s}_{i} , {v}_{i - 1} = - {s}_{i} , {y}_{i} = 0 , {r}_{i} = 0} , \qquad Equation ( 9 )$$
wherein f(sᵢ) is an exposure time for an i^{th} shot area, Dᵢ is an exposure area length of the i^{th} shot area, sᵢ is an exposure speed, tᵢ^{step} is the minimum step time, s_{m.i} is a minimum exposure speed at which exposure for the i^{th} shot area is possible, s_{M.i} is a maximum exposure speed at which exposure for the i^{th} shot area is possible, sᵢ^{y} is Equation (10), sir is Equation (11), and the sᵢ¹ is Equation (12),
$${s}_{i}^{y} = max ( min ( \sqrt{\frac{{D}_{i} max \cdot acc \cdot y}{2}} , {s}_{M \cdot i} ) , {s}_{my \cdot i} ) , \qquad Equation ( 10 )$$
$${s}_{i}^{r} = max ( min ( \sqrt{\frac{{D}_{i} max \cdot acc \cdot r}{2 k}} , {s}_{M \cdot i} ) , {s}_{mr \cdot i} ) , \qquad Equation ( 11 )$$
$${s}_{i}^{1} = \frac{{D}_{i}}{min 1 ShotTime - {t}_{i}^{step \cdot x}} , \qquad Equation ( 12 )$$
wherein s_{my.i} is an optimal exposure speed in the second direction at which the wafer stage moves in the second direction in the i^{th} shot area, in a case in which tᵢ^{step.x}, which is a minimum step time in the first direction during which the wafer stage moves in the first direction in the section in which exposure for the (i−1)^{th} shot area is completed and the exposure device moves to expose the i^{th} shot area, is equal to tᵢ^{step.y}, which is a minimum step time in the second direction during which the wafer stage moves in the second direction in the section in which exposure for the (i−1)^{th} shot area is completed and the exposure device moves to expose the i^{th} shot area,
s_{mr.i} may be an optimal exposure speed in the third direction at which the reticle stage moves in the third direction in the i^{th} shot area, in a case in which the minimum step time tᵢ^{step.x} in the first direction is equal to tᵢ^{step.r}, which is a minimum step time in the third direction during which the reticle stage moves in the third direction in the section in which exposure for the (i−1)^{th} shot area is completed and the exposure device moves to expose the i^{th} shot area,
tᵢ^{step.x} is obtained by using Equation (13):
$${t}_{i}^{step \cdot x} = {T}_{x} ( {x}_{i} , max \cdot vel \cdot x , \\ max \cdot acc \cdot x , max \cdot jerk \cdot x , max \cdot snap \cdot x , {T}_{s \cdot w} ) , \qquad Equation ( 13 )$$
tᵢ^{step.y} is obtained by using Equation (14):
$${t}_{i}^{step \cdot y} = {T}_{y} ( {y}_{i ,} , {s}_{My \cdot i} , max \cdot vel \cdot y , \\ max \cdot acc \cdot y , max \cdot jerk \cdot y , max \cdot snap \cdot y , {T}_{s \cdot w} ) , \qquad Equation ( 14 )$$
and
tᵢ^{step.r} is obtained by using Equation (15):
$${t}_{i}^{step . r} = {T}_{y} ( {r}_{i} , {ks}_{Mr . i} , max . vel . r , \\ max . acc . r , max . jerk . r , max . snap . r , {T}_{s . r} ) , \qquad Equation ( 15 )$$
wherein Tₓ is a time model for movement of the wafer stage in the first direction, T_{y} is a time model for movement of the wafer stage or the reticle stage in the second direction, xᵢ is a distance that the wafer stage moves in the first direction between an end position of exposure for the (i−1)^{th} shot area and a start position for the i^{th} shot area, yᵢ is a distance that the wafer stage moves in the second direction between the end position of exposure for the (i−1)^{th} shot area and the start position for the i^{th} shot area, rᵢ is a distance that the reticle stage moves in the third direction between the end position of exposure for the (i−1)^{th} shot area and the start position for the i^{th} shot area, T_{s.w} is a settling time of the wafer stage, T_{s.r} is a settling time of the reticle stage, s_{My.i} is a maximum exposure speed in the second direction in the i^{th} shot area, max.vel.x is a maximum speed of the wafer stage in the first direction, max.acc.x is a maximum acceleration of the wafer stage in the first direction, max.jerk.x is a maximum jerk of the wafer stage in the first direction, max.snap.x is a maximum snap of the wafer stage in the first direction, max.vel.y is a maximum speed of the wafer stage in the second direction, max.acc.y is a maximum acceleration of the wafer stage in the second direction, max.jerk.y is a maximum jerk of the wafer stage in the second direction, max.snap.y is a maximum snap of the wafer stage in the second direction, max.vel.r is a maximum speed of the reticle stage in the third direction, max.acc.r is maximum acceleration of the reticle stage in the third direction, max.jerk.r is a maximum jerk of the reticle stage in the third direction, max.snap.r is a maximum snap of the reticle stage in the third direction, and k is an exposure ratio.

8. The exposure equipment of claim 4, wherein the second estimation unit is further configured to divide shot areas of the wafer into a plurality of groups and an optimal exposure speed sᵢ* from among exposure speeds for each group by using Equation (16) and Equation (17):
$${s}_{i}^{*} = \begin{matrix}arg min \\ {s}_{i} ∈ \{ {s}_{m . i} , {s}_{i}^{y} , {s}_{i}^{r} , {s}_{i}^{1} , {s}_{i}^{0} , {s}_{M . i} \}\end{matrix} {f}_{G} ( {s}_{i} ) , \qquad Equation ( 16 )$$
$${{f}_{G} ( {s}_{i} ) = {\sum }_{i ∈ {G}_{i}} ( \frac{{D}_{i}}{{s}_{i}} + {t}_{i}^{step} \vert}_{{v}_{i} = {d}_{i} \cdot {s}_{i} , {v}_{i - 1} = {d}_{( i - 1 )} \cdot {s}_{( i - 1 )}} ) , \qquad Equation ( 17 )$$
wherein f_{G}(sᵢ) is an exposure time for an i^{th} group, Gⱼ is the group, Dᵢ is an exposure area length of an i^{th} shot area in the second direction, sᵢ is an exposure speed, dᵢ is an exposure direction, tᵢ^{step} is the minimum step time, s_{m.i} is a minimum exposure speed at which exposure for the i^{th} shot area is possible, s_{M.i} is a maximum exposure speed at which exposure for the i^{th} shot area is possible, sᵢ^{y} is Equation (18), sᵢ¹ is Equation (19), and sᵢ¹ is Equation (20),
$${s}_{i}^{y} = max ( min ( \sqrt{\frac{{D}_{i} max . acc . y}{2}} , {s}_{M . i} ) , {s}_{my . i} ) , \qquad Equation ( 18 )$$
$${s}_{i}^{r} = max ( min ( \sqrt{\frac{{D}_{i} max . acc . r}{2 k}} , {s}_{M . i} ) , {s}_{mr . i} ) , \qquad Equation ( 19 )$$
$${s}_{i}^{1} = \frac{{D}_{i}}{min 1 ShotTime - {t}_{i}^{step . x}} , \qquad Equation ( 20 )$$
wherein s_{my.i} is an optimal exposure speed in the second direction at which the wafer stage moves in the second direction in the i^{th} shot area, in a case in which tᵢ^{step.x}, which is a minimum step time in the first direction during which the wafer stage moves in the first direction in the section in which exposure for the (i−1)^{th} shot area is completed and the exposure device moves to expose the i^{th} shot area, is equal to tᵢ^{step.y}, which is a minimum step time in the second direction during which the wafer stage moves in the second direction in the section in which exposure for the (i−1)^{th} shot area is completed and the exposure device moves to expose the i^{th} shot area,
s_{mr.i} is an optimal exposure speed in the third direction at which the reticle stage moves in the third direction in the i^{th} shot area, in a case in which the minimum step time t₁^{step.x} in the first direction is equal to tᵢ^{step.r}, which is a minimum step time in the third direction during which the reticle stage moves in the third direction in the section in which exposure for the (i−1)^{th} shot area is completed and the exposure device moves to expose the i^{th} shot area,
t₁^{step.x} is obtained by using Equation (21):
$${t}_{i}^{step . x} = {T}_{x} ( {x}_{i} , max . vel . x , max . acc . x , max . jerk . x , max . snap . x , {T}_{s . w} ) , \qquad Equation ( 21 )$$
tᵢ^{step.y} is obtained by using Equation (22):
$${t}_{i}^{step . y} = {T}_{y} ( {y}_{i} , {s}_{My . i} , max . vel . y , \\ max . acc . y , max . jerk . y , max . snap . y , {T}_{s . w} ) , \qquad Equation ( 22 )$$
and
tᵢ^{step.r} is obtained by using Equation (23):
$${t}_{i}^{step . r} = {T}_{y} ( {r}_{i} , {ks}_{Mr . i} , max . vel . r , \\ max . acc . r , max . jerk . r , max . snap . r , {T}_{s . r} ) , \qquad Equation ( 23 )$$
wherein Tₓ is a time model for movement of the wafer stage in the first direction, T_{y} is a time model for movement of the wafer stage or the reticle stage in the second direction, xᵢ is a distance the wafer stage moves in the first direction between an end position of exposure for the (i−1)^{th} shot area and a start position for the i^{th} shot area, yᵢ is a distance that the wafer stage moves in the second direction between the end position of exposure for the (i−1)^{th} shot area and the start position for the i^{th} shot area, rᵢ is a distance the reticle stage moves in the third direction between the end position of exposure for the (i−1)^{th} shot area and the start position for the i^{th} shot area, T_{s.w} is a settling time of the wafer stage, T_{s.r} is a settling time of the reticle stage, s_{My.i} is a maximum exposure speed in the second direction in the i^{th} shot area, max.vel.x is a maximum speed of the wafer stage in the first direction, max.acc.x is a maximum acceleration of the wafer stage in the first direction, max.jerk.x is a maximum jerk of the wafer stage in the first direction, max.snap.x is a maximum snap of the wafer stage in the first direction, max.vel.y is a maximum speed of the wafer stage in the second direction, max.acc.y is a maximum acceleration of the wafer stage in the second direction, max.jerk.y is a maximum jerk of the wafer stage in the second direction, max.snap.y is a maximum snap of the wafer stage in the second direction, max.vel.r is a maximum speed of the reticle stage in the third direction, max.acc.r is maximum acceleration of the reticle stage in the third direction, max.jerk.r is a maximum jerk of the reticle stage in the third direction, max.snap.r is a maximum snap of the reticle stage in the third direction, and k is an exposure ratio.

9. The exposure equipment of claim 4, wherein the comparison unit is further configured to compare the minimum step time calculated from the first the first estimation unit with a measured step time, or calculate an optimal wafer exposure time from the minimum step time and the scan time and compares the optimal wafer exposure time with the measured wafer exposure time.

10. The exposure equipment of claim 4, wherein the comparison unit is further configured to calculate the wafer exposure time from the optimal exposure speed calculated from the second estimation unit and compare the calculated wafer exposure time with the measured wafer exposure time.

11. The exposure equipment of claim 1, further comprising an interface unit capable of exchanging information with the exposure device.

12. Exposure equipment comprising:
an exposure device configured to transfer a pattern of a reticle to a wafer by using light; and
a wafer exposure time inspection device configured to inspect appropriateness of a wafer exposure time during which the wafer is illuminated to transfer the pattern to the wafer,
wherein the wafer exposure time inspection device comprises:
an estimation unit configured to estimate a minimum step time or an optimal exposure speed, wherein, in the minimum step time, a step time during which exposure for one shot area from among a plurality of shot areas on the wafer is completed and the wafer exposure device moves to a next shot area is minimized, and in the optimal exposure speed, a sum of the step time and a scan time during which the shot area is exposed is minimized;
a comparison unit configured to compare a measured wafer exposure time with a first optimal wafer exposure time calculated from the minimum step time and the scan time or compare a measured wafer exposure time with a second optimal wafer exposure time calculated from the estimated optimal exposure speed; and
a check unit configured to identify whether an exposure speed is set in the exposure device, and
in the optimal wafer exposure time, a sum of a wafer exposure time, which is a sum of a scan time during which each of all shot areas of the wafer is exposed, with a step time during which the exposure device moves between the shot areas is minimized.

13. The exposure equipment of claim 12, wherein the exposure device comprises:
a reticle stage on which a reticle having a pattern formed therein is arranged;
an ultriviolet (UV) source configured to generate UV light and emit the generated UV light toward the reticle;
a first optical system configured to allow the UV light from the UV source to be incident on the reticle;
a second optical system in which the reticle transmits the UV light that is reflected, refracted, or transmitted; and
a wafer stage on which a wafer through which the UV light passing through the second optical system is projected and to which the pattern is transferred is arranged.

14. The exposure equipment of claim 12, wherein the exposure device comprises:
an illumination source configured to generate and emit light;
a reticle stage which transmits light generated from the illumination source and on which a reticle is arranged;
a transparent optical system that projects light passing through the reticle; and
a wafer stage on which a wafer through which the light passing through the transparent optical system is projected and to which the pattern is transferred is arranged.

15. The exposure equipment of claim 12, wherein the estimation unit is further configured to estimate the minimum step time or the optimal exposure speed by modeling, by using at least a 3rd-order system, a time model for each of displacement of a wafer stage of the exposure device in a first direction, displacement of the wafer stage in a second direction, and displacement of a reticle stage in a third direction, and
the first direction is perpendicular to the second direction in which the shot area is exposed, and the third direction is parallel to the second direction.

16. The exposure equipment of claim 15, wherein the estimation unit comprises a first estimation unit and a second estimation unit,
when it is identified by the check unit that the exposure speed is set to a certain value, the first estimation unit is configured to estimate the minimum step time, and
when it is identified by the check unit that the exposure speed is set to a certain range, the second estimation unit is configured to calculate the optimal exposure speed.

17. The exposure equipment of claim 16, wherein the first estimation unit is configured to estimate the minimum step time tᵢ^{step} by using Equation (1):
$${t}_{i}^{step} = max ( {t}_{i}^{step . x} , {t}_{i}^{step . y} , {t}_{i}^{step . r} , min StepTime , min 1 ShotTime - \frac{{D}_{i}}{\vert {v}_{i} \vert} ) , \qquad Equation ( 1 )$$
wherein t₁^{step.x} is a minimum step time in the first direction during which the wafer stage moves in the first direction in a section in which exposure for an (i−1)^{th} shot area is completed and the exposure device moves to expose an i^{th} shot area, tᵢ^{step.y} is a minimum step time in the second direction during which the wafer stage moves in the second direction in a section in which exposure for the (i−1)^{th} shot area is completed and the exposure device moves to expose the i^{th} shot area, tᵢ^{step.r} is a minimum step time in the third direction during which the reticle stage moves in the third direction in a section in which exposure for the (i−1)^{th} shot area is completed and the exposure device moves to expose the i^{th} shot area, minStepTime is a set minimum step time that is input to the exposure device, min1ShotTime is a set minimum one-shot time that is input to the exposure device, Dᵢ is an exposure area length of the i^{th} shot area in the second direction, and vᵢ is the exposure speed that is set,
t₁^{step.x} is obtained by using Equation (2):
$${t}_{i}^{step . x} = {T}_{x} ( {x}_{i} , max . vel . x , max . acc . x , max . jerk . x , max . snap . x , {T}_{s . w} ) , \qquad Equation ( 2 )$$
tᵢ^{step.y} is obtained by using Equation (3):
$${t}_{i}^{step . y} = {T}_{y} ( {y}_{i} , {v}_{i - 1} , {v}_{i} , max . vel . y , \\ max . acc . y , max . jerk . y , max . snap . y , {T}_{s . w} ) , \qquad Equation ( 3 )$$
and
tᵢ^{step.r} is obtained by using Equation (4):
$${t}_{i}^{step . r} = {T}_{y} ( {r}_{i} , {kv}_{i - 1} , {kv}_{i} , max . vel . r , \\ max . acc . r , max . jerk . r , max . snap . r , {T}_{s . r} ) , \qquad Equation ( 4 )$$
wherein Tₓ is a time model for movement of the wafer stage in the first direction, T_{y} is a time model for movement of the wafer stage or the reticle stage in the second direction, xᵢ is a distance that the wafer stage moves in the first direction between an end position of exposure for the (i−1)^{th} shot area and a start position for the i^{th} shot area, yᵢ is a distance that the wafer stage moves in the second direction between the end position of exposure for the (i−1)^{th} shot area and the start position for the i^{th} shot area, rᵢ is a distance that the reticle stage moves in the third direction between the end position of exposure for the (i−1)^{th} shot area and the start position for the i^{th} shot area, T_{s.w} is a settling time of the wafer stage, T_{s.r} is a settling time of the reticle stage, vᵢ₋₁ is an exposure speed is an exposure speed in the (i−1)^{th} shot area, vᵢ is an exposure speed in the i^{th} shot area, max.vel.x is a maximum speed of the wafer stage in the first direction, max.acc.x is a maximum acceleration of the wafer stage in the first direction, max.jerk.x is a maximum jerk of the wafer stage in the first direction, max.snap.x is a maximum snap of the wafer stage in the first direction, max.vel.y is a maximum speed of the wafer stage in the second direction, max.acc.y is a maximum acceleration of the wafer stage in the second direction, max.jerk.y is a maximum jerk of the wafer stage in the second direction, max.snap.y is a maximum snap of the wafer stage in the second direction, max.vel.r is a maximum speed of the reticle stage in the third direction, max.acc.r is maximum acceleration of the reticle stage in the third direction, max.jerk.r is a maximum jerk of the reticle stage in the third direction, max.snap.r is a maximum snap of the reticle stage in the third direction, and k is an exposure ratio.

18. The exposure equipment of claim 16, wherein the second estimation unit is further configured to estimate the optimal exposure speed (sᵢ*) by using Equation (8) and Equation (9):
$${s}_{i}^{*} = \begin{matrix}arg min \\ {s}_{i} ∈ \{ {s}_{m . i} , {s}_{i}^{y} , {s}_{i}^{r} , {s}_{i}^{1} , {s}_{i}^{0} , {s}_{M . i} \}\end{matrix} f ( {s}_{i} ) , \qquad Equation ( 8 )$$
$${f ( {s}_{i} ) = \frac{{D}_{i}}{{s}_{i}} + {t}_{i}^{step} \vert}_{{v}_{i} = {s}_{i} , {v}_{i - 1} = - {s}_{i} , {y}_{i} = 0 , {r}_{i} = 0} , \qquad Equation ( 9 )$$
wherein f(sᵢ) is an exposure time for an i^{th} shot area, Dᵢ is an exposure area length of the i^{th} shot area, sᵢ is an exposure speed, tᵢ^{step} is the minimum step time, s_{m.i} is a minimum exposure speed at which exposure for the i^{th} shot area is possible, s_{M.i} is a maximum exposure speed at which exposure for the i^{th} shot area is possible, sᵢ^{y} is Equation (10), sᵢ¹ is Equation (11), and the sᵢ¹ is Equation (12),
$${s}_{i}^{y} = max ( min ( \sqrt{\frac{{D}_{i} max . acc . y}{2}} , {s}_{M . i} ) , {s}_{my . i} ) , \qquad Equation ( 10 )$$
$${s}_{i}^{r} = max ( min ( \sqrt{\frac{{D}_{i} max . acc . r}{2 k}} , {s}_{M . i} ) , {s}_{mr . i} ) , \qquad Equation ( 11 )$$
$${s}_{i}^{1} = \frac{{D}_{i}}{min 1 ShotTime - {t}_{i}^{step . x}} , \qquad Equation ( 12 )$$
wherein s_{my.i} is an optimal exposure speed in the second direction at which the wafer stage moves in the second direction in the i^{th} shot area, in a case in which tᵢ^{step.x}, which is a minimum step time in the first direction during which the wafer stage moves in the first direction in the section in which exposure for the (i−1)^{th} shot area is completed and the exposure device moves to expose the i^{th} shot area, is equal to tᵢ^{step.y}, which is a minimum step time in the second direction during which the wafer stage moves in the second direction in the section in which exposure for the (i−1)^{th} shot area is completed and the exposure device moves to expose the i^{th} shot area,
s_{mr.i} is an optimal exposure speed in the third direction at which the reticle stage moves in the third direction in the i^{th} shot area, in a case in which the minimum step time t₁^{step.x} in the first direction is equal to tᵢ^{step.r}, which is a minimum step time in the third direction during which the reticle stage moves in the third direction in the section in which exposure for the (i−1)^{th} shot area is completed and the exposure device moves to expose the i^{th} shot area,
t₁^{step.x} is obtained by using Equation (13):
$${t}_{i}^{step . x} = {T}_{x} ( {x}_{i} , max . vel . x , max . acc . x , max . jerk . x , max . snap . x , {T}_{s . w} ) , \qquad Equation ( 13 )$$
tᵢ^{step.y} is obtained by using Equation (14):
$${t}_{i}^{step . y} = \qquad Equation ( 14 )$$
$${T}_{y} ( {y}_{i ,} , {s}_{My . i} , max . vel . y , max . acc . y , max . jerk . y , max . snap . y , {T}_{s . w} ) ,$$
and
tᵢ^{step.r} is obtained by using Equation (15):
$${t}_{i}^{step . r} = {T}_{y} ( {r}_{i} , {ks}_{Mr . i} , max . vel . r , \\ max . acc . r , max . jerk . r , max . snap . r , {T}_{s . r} ) , \qquad Equation ( 15 )$$
wherein Tₓ is a time model for movement of the wafer stage in the first direction, T_{y} is a time model for movement of the wafer stage or the reticle stage in the second direction, xᵢ is a distance the wafer stage moves in the first direction between an end position of exposure for the (i−1)^{th} shot area and a start position for the i^{th} shot area, yᵢ is a distance the wafer stage moves in the second direction between the end position of exposure for the (i−1)^{th} shot area and the start position for the i^{th} shot area, rᵢ is a distance the reticle stage moves in the third direction between the end position of exposure for the (i−1)^{th} shot area and the start position for the i^{th} shot area, T_{s.w} is a settling time of the wafer stage, T_{s.r} is a settling time of the reticle stage, s_{My.i} is a maximum exposure speed in the second direction in the i^{th} shot area, max.vel.x is a maximum speed of the wafer stage in the first direction, max.acc.x is a maximum acceleration of the wafer stage in the first direction, max.jerk.x is a maximum jerk of the wafer stage in the first direction, max.snap.x is a maximum snap of the wafer stage in the first direction, max.vel.y is a maximum speed of the wafer stage in the second direction, max.acc.y is a maximum acceleration of the wafer stage in the second direction, max.jerk.y is a maximum jerk of the wafer stage in the second direction, max.snap.y is a maximum snap of the wafer stage in the second direction, max. vel.r is a maximum speed of the reticle stage in the third direction, max.acc.r is maximum acceleration of the reticle stage in the third direction, max.jerk.r is a maximum jerk of the reticle stage in the third direction, max.snap.r is a maximum snap of the reticle stage in the third direction, and k is an exposure ratio.

19. Exposure equipment comprising:
an exposure device configured to transfer a pattern of a reticle to a wafer by using light; and
a wafer exposure time inspection device configured to inspect appropriateness of a wafer exposure time during which the wafer is illuminated to transfer the pattern to the wafer,
wherein the wafer exposure time inspection device comprises:
an estimation unit configured to estimate a minimum step time or an optimal exposure speed, wherein, in the minimum step time, a step time during which exposure for one shot area from among a plurality of shot areas on the wafer is completed and the exposure device moves to a next shot area is minimized, and in the optimal exposure speed, a sum of the step time and a scan time during which the shot area is exposed is minimized;
a comparison unit configured to compare a measured wafer exposure time with a first optimal wafer exposure time calculated from the minimum step time and the scan time or compare a measured wafer exposure time with a second optimal wafer exposure time calculated from the estimated optimal exposure speed; and
a check unit configured to identify whether an exposure speed is set in the exposure device,
in the optimal wafer exposure time, a sum of a wafer exposure time, which is a sum of a scan time during which each of all shot areas of the wafer is exposed, with a step time during which the exposure device moves between the shot areas is minimized,
the exposure device comprises:
a reticle stage on which a reticle having a pattern formed therein is arranged;
an illumination source configured to generate ultraviolet (UV) light and emit the generated UV light toward the reticle;
a first optical system configured to allow the UV light from the UV source to be incident on the reticle;
a second optical system in which the reticle transmits the UV light that is reflected, refracted, or transmitted; and
a wafer stage on which a wafer through which the UV light passing through the second optical system is projected and to which the pattern is transferred is arranged,
the estimation unit is further configured to estimate the minimum step time or the optimal exposure speed by modeling, by using at least a 3rd-order system, a time model for each of displacement of a wafer stage of the exposure device in a first direction, displacement of the wafer stage in a second direction, and displacement of a reticle stage in a third direction, and
the first direction is perpendicular to the second direction in which the shot area is exposed, and the third direction is parallel to the second direction.

20. The exposure equipment of claim 19, wherein the estimation unit comprises a first estimation unit and a second estimation unit,
when it is identified by the check unit that the exposure speed is set to a certain value, the first estimation unit is configured to estimate the minimum step time, and
when it is identified by the check unit that the exposure speed is set to a certain range, the second estimation unit is configured to calculate the optimal exposure speed.
